(19) United States
(12) Patent Application Publication
(10) Pub. No.: US 2020/0381569 A1
(43) Pub. Date: Dec. 3, 2020

(54) WIRING MATERIAL, SOLAR CELL USING SAME, AND SOLAR CELL MODULE

(71) Applicant: KANEKA CORPORATION, Osaka (JP)

(72) Inventors: Shinya OMOTO, Osaka (JP); Junichi NAKAMURA, Osaka (JP); Toru TERASHITA, Osaka (JP); Gensuke KOIZUMI, Osaka (JP); Kohei KOJIMA, Osaka (JP)

(73) Assignee: KANEKA CORPORATION, Osaka (JP)

(21) Appl. No.: 16/998,713

(22) Filed: Aug. 20, 2020

Related U.S. Application Data
(63) Continuation of application No. PCT/JP2019/006112, filed on Feb. 19, 2019.

(30) Foreign Application Priority Data
Feb. 21, 2018 (JP) 2018-028466

(51) Int. Cl. H01L 31/05

(52) U.S. Cl. CPC H01L 31/0504; H01L 31/0516

(57) ABSTRACT

A wiring member for transporting a carrier generated in a solar cell includes: an assembled wire that is an assembly of wires; and an insulating resin body that encapsulates the assembled wire and exhibits adhesion upon application of energy.

### CROSS-REFERENCE TO RELATED APPLICATIONS

This is a continuation of International Application No. PCT/JP2019/006112 filed on Feb. 19, 2019, which claims priority to Japanese Patent Application No. 2018-028466 filed on Feb. 21, 2018. The entire disclosures of these applications are incorporated by reference herein.

### BACKGROUND

The present invention relates to a wiring member, and a solar cell and a solar cell module using the wiring member.

In a solar cell module obtained by connecting a plurality of solar cells in series, a tab wire, which is called a “rectangular member,” serves as a wiring member electrically connecting the solar cells together. The tab wire is generally made of a copper, for example, in the shape of a ribbon coated with a solder material.

With the use of a rectangular tab wire as a wiring member, a high temperature of 200° C. or higher is usually generated in soldering solar cells, whereby the solar cells may warp. In addition, the rectangular wiring member has poor flexibility, that is, high rigidity. The stress generated at the interface between the solar cells and the wiring member or between the solar cells and the encapsulant encapsulating the solar cells may warp the solar cells, whereby the long-term reliability decreases.

To address the problem, Japanese Unexamined Patent Publication No. 2016-186842 discloses a coated conductive wire that integrates a tab wire and a collector of a solar cell, and describes a configuration using, as the coated conductive wire, a conductive resin obtained by adding metal powder to an insulating resin.

### SUMMARY

The present invention is directed to a wiring member for transporting a carrier generated in a solar cell, the wiring member including: an assembled wire that is an assembly of wires; and an insulating resin body that encapsulates the assembled wire and exhibits adhesion upon application of energy.

The present invention is directed to a solar cell connected to the wiring member according to the present invention, wherein the wiring member is a current collecting wire that collects the carrier, and in a part of the current collecting wire applied with the energy and pressurized, only the wires form an electrically connected portion to the solar cell.

The present invention is directed to a solar cell module in which the solar cells according to the present invention are electrically connected by the current collecting wire.

### BRIEF DESCRIPTION OF THE DRAWINGS

FIG. 1 is a schematic partial cross-sectional view showing double-sided electrode type solar cells using current collecting wires, each of which serves as a wiring member according to an embodiment, and a solar cell module including the solar cells.

FIG. 2 is a schematic partial cross-sectional view showing back-electrode type solar cells using current collecting wires, each of which serves as the wiring member according to the embodiment, and a solar cell module including the solar cells.

FIG. 3 is a schematic partial cross-sectional view showing an example double-sided electrode type solar cell according to the embodiment.

FIG. 4 is a schematic partial cross-sectional view showing an example back-electrode type solar cell according to the embodiment.

FIG. 5 is a top view and a cross-sectional view, taken along line V-V of FIG. 5, showing a current collecting wire that serves as the wiring member according to the embodiment.

FIG. 6 is a cross-sectional view showing a step in a method of connecting the current collecting wire according to the embodiment to a connection member.

FIG. 7 is a cross-sectional view showing another step in the method of connecting the current collecting wire according to the embodiment to the connection member.

FIG. 8 is a cross-sectional view showing a state in which the current collecting wire according to the embodiment is connected to the connection member.

FIG. 9 is a top view showing back-electrode type solar cells connected by current collecting wires according to a first example.

FIG. 10 is an enlarged partial top view of a connection region A of FIG. 9.

FIG. 11 is a top view showing back-electrode type solar cells connected by current collecting wires according to a second example.

FIG. 12 is an enlarged partial top view of a region B of FIG. 11.

FIG. 13 is an enlarged partial cross-sectional view of a region C of FIG. 12.

FIG. 14 is a top view showing the back-electrode type solar cells connected by the current collecting wires according to the second example.

FIG. 15 is a schematic top view showing double-sided electrode type solar cells connected by current collecting wires according to a third example.

### DETAILED DESCRIPTION

Now, an embodiment will be described with reference to the drawings.

(Solar Cell Module)

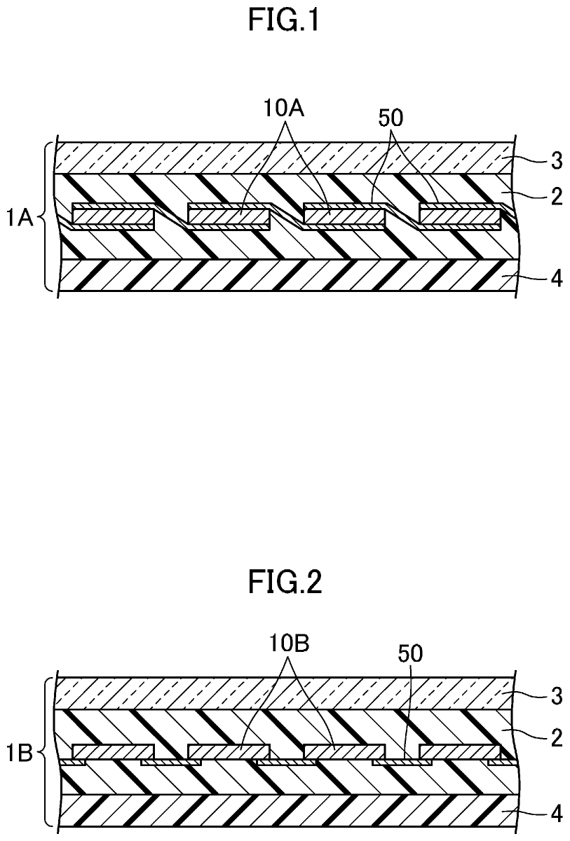

Each of FIGS. 1 and 2 schematically shows a part of a solar cell module 1 (1A/1B) including a plurality of solar cells 10 (10A/10B) connected together by current collecting wires 50 according to the embodiment. FIG. 1 is a cross-sectional view of the module using double-sided electrode type solar cells 10A. FIG. 2 is a cross-sectional view of the module using back-electrode type solar cells 10B. FIGS. 1 and 2 focus on how to electrically connect the solar cells 10 (10A/10B) together using the current collecting wires 50.

Mounted in the solar cell module 1A shown in FIG. 1 are the double-sided electrode type solar cells 10A each of which includes n-side electrodes (or p-side electrodes) on one major surface and p-side electrodes (or n-side electrodes) on the other major surface. The double-sided electrode type solar cells 10A are electrically connected in series by the current collecting wires 50. The current collecting wires 50 are example wiring members. Both the major surfaces of these double-sided electrode type solar cells 10A connected in series are encapsulated by an encapsulant 2. In addition, a protective member 3 for the light receiving surface is located on the front surface (i.e., the light receiving surface) of the encapsulant 2, whereas a protective member 4 for the back surface is located on the back surface of the encapsulant 2.

Mounted in the solar cell module 1B shown in FIG. 2 are the back-electrode type solar cells 10B each of which includes, on one major surface, n- and p-side electrodes that are electrically disconnected from each other. The back-electrode type solar cells 10B are electrically connected in series by the current collecting wires 50. More specifically, an n-side electrode of one solar cell 10B and a p-side electrode of the adjacent solar cell 10B are electrically connected in series. These back-electrode type solar cells 10B connected in series are encapsulated by an encapsulant 2. In addition, a protective member 3 for the light receiving surface is located on the light receiving surface of the encapsulant 2, whereas a protective member 4 for the back surface is located on the back surface of the encapsulant 2.

The encapsulant 2 may be made of, for example, a light-transmissive resin such as an ethylene/vinyl acetate copolymer (EVA), an ethylene/α-olefin copolymer, ethylene/vinyl acetate/triallyl isocyanurate (EVAT), polyvinyl butyrate (PVB), an acrylic resin, a urethane resin, or a silicon resin.

Although not particularly limited, the protective member 3 for the light receiving surface may be made of a material that is light-transmissive and resistant to ultraviolet light. For example, glass or a transparent resin such as an acrylic resin or a polycarbonate resin is used.

Although not particularly limited, the protective member 4 for the back surface may be made of a material that reduces the entry of water or the like, that is, a material with high water shielding properties in one preferred embodiment. For example, a multilayer of a resin film such as polyethylene terephthalate (PET), polyethylene (PE), an olefin-based resin, a fluorine-containing resin, or a silicone-containing resin, and a metal foil such as an aluminum foil is used.

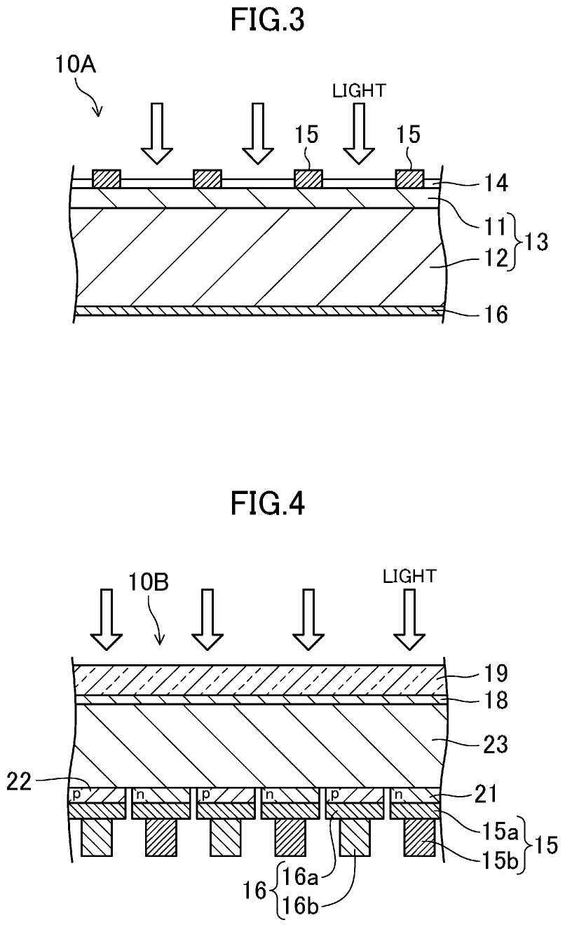

FIG. 3 schematically shows an example cross section of a double-sided electrode type solar cell 10A. As shown in FIG. 3, the double-sided electrode type solar cell 10A includes, for example, a semiconductor substrate 13 formed by depositing an n-type impurity diffusion layer (i.e., an n-type semiconductor layer) 11 on a surface of a p-type silicon substrate 12. Such the semiconductor substrate 13 has a p-n junction, and includes, for example, the n-type semiconductor layer 11 made of n-type silicon on the front surface (i.e., the light receiving surface) and the p-type silicon substrate 12 on the back surface. Note that the semiconductor substrate 13 may have, on its front surface, an antireflection film 14 reducing reflection of the received light. In addition, selectively provided on the n-type semiconductor layer 11 are, as grid electrodes, for example, n-side electrodes 15 in electrical conduction with the n-type semiconductor layer 11. Provided on, for example, the entire surface of the p-type silicon substrate 12 is a p-side electrode 16 in electrical conduction with the p-type silicon substrate 12. Note that the double-sided electrode type solar cell 10A is not limited to the semiconductor substrate 13 with the p-type silicon substrate 12 as the main body, but may employ, for example, a semiconductor substrate formed by depositing a p-type semiconductor layer on the front surface of an n-type silicon substrate. In addition, the conductivity types of the silicon substrate or the semiconductor layer on the light receiving surface may be p or n. Note that, with respect to the conductivity type, for example, if the p-type is a first conductivity type, the n-type may be referred to as a second conductivity type. In short, one of opposite conductivity types is referred to as the first conductivity type, and the other as the second conductivity type.

FIG. 4 schematically shows an example cross-sectional structure of a back-electrode type solar cell 10B. As shown in FIG. 4, the back-electrode type solar cell 10B includes, for example, an n-type silicon substrate 23 that serves as a photoelectric converter. Located on one major surface, namely, the back surface, which is opposite to the light receiving surface, of the n-type silicon substrate 23 are, for example, a comb-like n-type semiconductor layer 21 and a comb-like p-type semiconductor layer 22. These semiconductor layers are arranged such that shafts of the respective semiconductor layers face each other and that the teeth of the semiconductor layers mesh with each other. Provided on the n-type semiconductor layer 21 are n-side electrodes 15 (15a, 15b). Provided on the p-type semiconductor layer 22 are p-side electrodes 16 (16a, 16b).

Each electrode 15 or 16 includes a multilayer of a transparent conductive film 15a or 16a made of a transparent conductive oxide, and a metal film 15b or 16b in one preferred embodiment. The transparent conductive oxide is, for example, a zinc oxide, an indium oxide, or a tin oxide alone or in a mixture. In view of the conductivity, the optical characteristics, and the long-term reliability, an indium-based oxide containing an indium oxide as a main component is used in one preferred embodiment. Out of indium oxides, an indium tin oxide (ITO) is used as a main component in one preferred embodiment.

The electrode on the shaft of each semiconductor layer 21 or 22 is referred to as a “bus bar electrode”, and electrodes on the comb teeth as “finger electrodes.”

Note that an antireflection film 18 may be formed on the front surface (i.e., the light receiving surface) of the n-type silicon substrate 23. Located on the antireflection film 18 is, for example, a transparent glass as a transparent protective plate 19 protecting the n-type silicon substrate 23. In addition, the crystal substrate included in the back-electrode type solar cell 10B is not limited to the n-type silicon substrate 23 but may be, for example, a p-type silicon substrate.

The types of the solar cells 10A and 10B shown in FIGS. 3 and 4 are not particularly limited. Any of silicon solar cells (e.g., thin-film or crystal solar cells), compound solar cells, or organic solar cells (e.g., dye-sensitized or organic thin-film solar cells) may be used. In addition, the type of the electrodes 15 (e.g., the double-sided electrode type or the back-electrode type) is also not particularly limited.

(Current Collecting Wire)

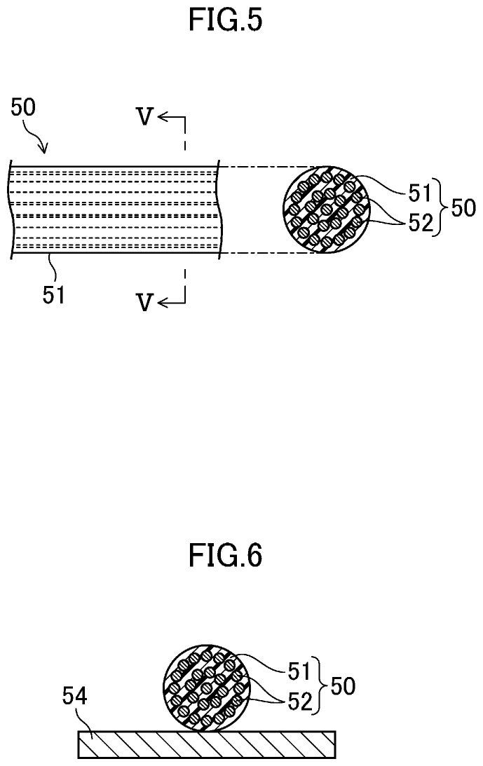

FIG. 5 shows a current collecting wire according to the embodiment. In FIG. 5, the left is a top view (specifically, a partial top view) of the current collecting wire 50, whereas the right is a cross-sectional view taken along line V-V in the left view. As shown in FIG. 5, the current collecting wire 50 according to the embodiment includes an assembled wire 52 that is an assembly of a plurality of wires, and an insulating resin body 51 that encapsulates the assembled wire 52 and exhibits adhesion upon application of energy.

The current collecting wire 50 is a wiring member that collects and transports carriers generated in the solar cells 10. The assembled wire 52 may be a braided wire obtained by braiding a plurality of wires or may be a stranded wire obtained by twisting a plurality of wires together as long as it is an assembly of a plurality of wires.

The energy to be applied may be, for example, heat energy or light (ultraviolet) energy. The insulating resin body 51 is thus a thermosetting resin or a light (ultraviolet) curable resin. The material of the insulating resin body 51 may be an epoxy resin, a urethane resin, a phenoxy resin, or an acrylic resin. In a case in which the current collecting wires 50 according to the embodiment are used for the solar cells 10A or 10B, for example, a modifier such as a silane-based coupling agent, a titanate-based coupling agent, or an aluminate-based coupling agent may be added to the insulating resin body 51 to improve the adhesion and wettability with the electrodes or the other wiring members. In addition, in order to control the elastic modulus and the tackiness, a rubber component such as acrylic rubber, silicon rubber, or urethane rubber may be added to the insulating resin body 51.

The current collecting wire 50 according to the embodiment is not necessarily covered with the insulating resin body 51 throughout the entire length of the assembled wire 52 in the extension direction or throughout the entire circumference of the assembled wire 52. That is, depending on the application spot or the specifications, the parts of the current collecting wire 50 connected to necessary connection targets such as the electrodes may be covered with at least the insulating resin body 51.

Note that, if the assembled wire 52 is a braided wire obtained by braiding wires or a stranded wire obtained by twisting wires together, the insulating resin body 51 fills at least a part of the gaps between the wires.

If the insulating resin body 51 is made of a light-curable resin with a high fluidity before curing, the insulating resin body 51 itself may be subjected to a temporary curing treatment (pre-curing treatment) to the extent that allows holding of the assembled wire 52.

(Method for Connecting Current Collecting Wire)

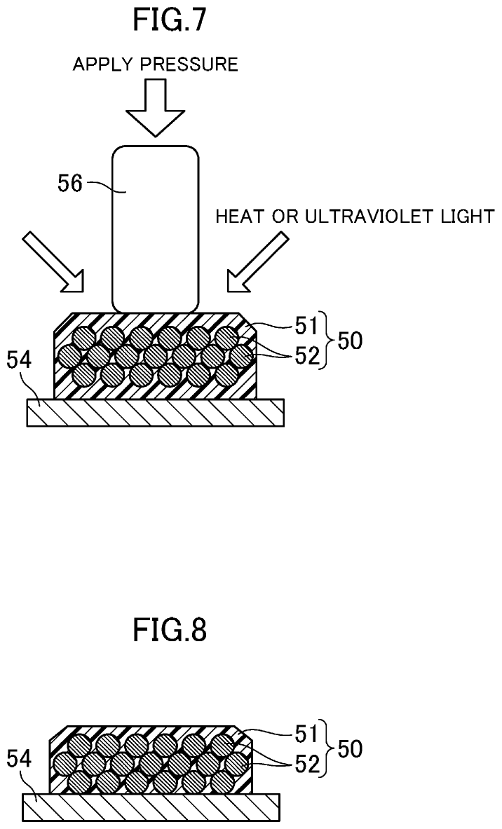

FIGS. 6 to 8 show a method of connecting the current collecting wire 50 according to the embodiment. For convenience, FIGS. 7 and 8 are enlarged views of the current collecting wire 50 in FIG. 6.

First, as shown in FIG. 6, the current collecting wire 50 is located at a predetermined position of a conductive connection member (connection target) 54 corresponding to an electrode pad, for example.

Next, as shown in FIG. 7, the overlap in the connection region of the current collecting wire 50 on the connection member 54 is pressurized by a pressurizing jig 56 while being applied with predetermined energy. The predetermined energy is heat if the insulating resin body 51 of the current collecting wire 50 is a thermosetting resin, and the insulating resin body 51 is heated to about 150° C., for example. The heating means is not particularly limited and may be a heating lamp or a heater, for example. Alternatively, the heating means may be, like a soldering iron, included in the pressurizing jig 56 itself. If the insulating resin body 51 of the current collecting wire 50 is an ultraviolet curable resin, the wavelength of the ultraviolet light is not particularly limited but may range, for example, from about 200 nm to about 400 nm. With respect to the pressure at the time of pressurization, the maximum value is less than 10 MPa, whereas the minimum value is the pressure at which the current collecting wire 50 and the connection member 54 are in electrical conduction with a low resistance. As an example, the pressure may range from 0.6 MPa to 1.0 MPa.

In a case in which a conductive film or a conductive adhesive is used to electrically connect the electrodes of the solar cell and the conductive wiring, metal particles contained in the conductive film or the like generally come into physical contact with each other to be a series of conductive lines which needs to pass between the electrodes and the conductive wiring. Therefore, the conductive film, for example, needs to have a high pressure of about 10 MPa.

However, the current collecting wire 50 according to the embodiment includes the assembled wire 52 having the braided wires therein, instead of metal particles. There is thus no need to cause the physical contact between the metal particles, and the current collecting wire 50 passes between the electrodes and the conductive wiring at the relatively low pressure ranging from 0.6 MPa to 1.0 MPa.

Next, FIG. 8 shows a state in which the insulating resin body 51 of the current collecting wire 50 is cured. As shown in FIG. 8, the insulating resin body 51 of the current collecting wire 50 is pressure-bonded and cured to be connected to the surface of the connection member 54. In this case, the wires located in lower portions (i.e., forward ends in the pressurizing direction) of the assembled wire 52 included in the current collecting wire 50 come into contact with the connection member 54. Accordingly, the current collecting wire 50 and the connection member 54 are in electrical conduction.

That is, in the part of the current collecting wire 50 applied with the energy and pressurized, only the wires are electrically connected to the connection member 54 (and eventually the solar cells 10). In other words, in the part of the current collecting wire 50 applied with the energy and pressurized, only the insulating resin body 51 physically adheres to the connection member 54 (and eventually the solar cells 10).

As described above, the current collecting wire 50 according to the embodiment is selectively connected to the connection member 54 by selectively receiving the pressure at its part facing the connection region of the connection member 54. Therefore, the part of the current collecting wire 50 neither adhering to nor electrically connected to the connection member 54 is insulated from the connection member 54. That is, the part of the current collecting wire 50 neither adhering to nor electrically connected to the connection member 54 retains the flexibility.

In addition, there is no need to prepare an extra adhesive such as solder, whereby the costs of the material decrease and the throughput improves at the time of manufacture. Since no solder material is used, no solder material soaks into the braided wire or the like, whereby the current collecting wire 50 is prevented from being rigidified by the solder material. In a case in which the braided wire is used for interconnection, since the braided wire is encapsulated in the insulating resin body 51, the braided wire is hardly unbraided, which improves the workability and reduces short-circuiting with other nearby electrodes or the like.

In a case in which the current collecting wire 50 according to the embodiment is obtained by encapsulating the entire metal assembled wire 52 in the insulating resin body 51, the assembled wire 52 does not come into direct contact with the atmosphere and hardly rusts. Thus, the long-term storage properties as the wiring member improve. In addition, the reliability after the wiring increases.

### First Example

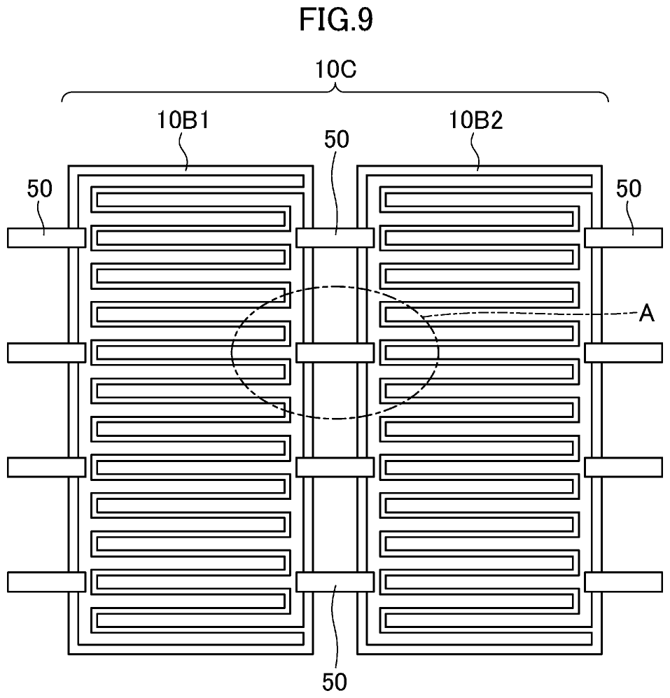

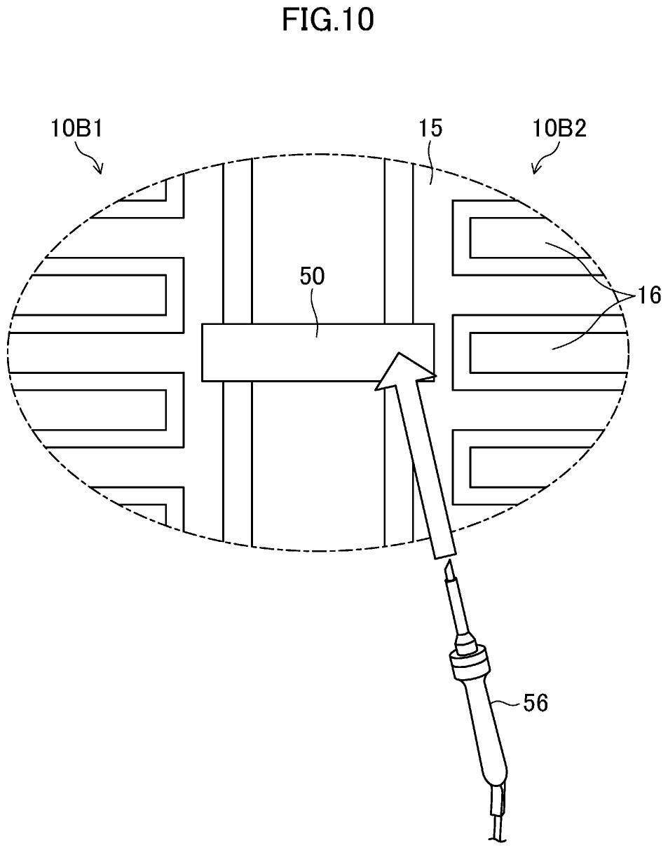

Now, back-electrode type solar cells 10B1 and 10B2 using the current collecting wires 50 according to the embodiment are shown as a first example in FIGS. 9 and 10. FIGS. 9 and 10 are top views of the back surfaces that are opposite to the light receiving surfaces.

As shown in FIG. 9, the first example employs the current collecting wires 50 to electrically connect the first and second back-electrode type solar cells 10B1 and 10B2 that have the same specifications. Such the electrical connection between the plurality of solar cells 10B1 and 10B2 in series by the current collecting wires 50 will be referred to as a “cell string 10C.” The cell string 10C is typically configured by connecting about fifteen solar cells 10 together. Some of them are shown in the figure.

FIG. 10 is a partial enlarged view of a connection region A shown in FIG. 9. As shown in FIG. 10, each end of the current collecting wire 50 is located on the electrode pad (not shown) of one of the first and second solar cells 10B1 and 10B2. After that, as described above, the current collecting wire 50 is electrically connected by heating and pressurizing using, for example, the soldering iron 56. The heating temperature of the soldering iron 56 at this time may be set to 180° C. or lower.

According to the first example, the current collecting wire 50 includes the assembled wire 52 and the insulating resin body 51 that encapsulates the assembled wire 52. Since the flexibility of these members reduces the warp and stress distortion of the solar cells 10B, the long-term reliability increases.

As shown in FIG. 10, the right insulating resin body 51 in the region other than the part of the current collecting wire 50 electrically connected by heating and pressurizing using the soldering iron 56 is not necessarily cured. The entire insulating resin body 51 is cured when the plurality of solar cells 10B are heated and pressure-bonded, and thereby encapsulated, while being sandwiched, via the encapsulant 2, between protective member 3 for the light receiving surface and the protective member 4 for the back surface.

In this first example, the plurality of solar cells 10B are merged into a string using the current collecting wire 50, and the entire cell string 10C is less warped. For example, in a case in which originally warped solar cells are merged into a string and a typical rectangular wire is used for electrical connection between the cells, the warp per solar cell is added.

By contrast, in the use of the current collecting wire 50 according to the embodiment, the warp per solar cell is not simply added but compensated between the cells by the flexible current collecting wire 50. Accordingly, the amount of warp of the cell string 10C is greatly reduced. That is, when focusing on a single solar cell 10B, the warp per solar cell is reduced after forming the cell string 10C with the use of the current collecting wire 50 according to this embodiment as compared to the case using the typical rectangular wire.

In addition, no solder material is used for the current collecting wire 50. Thus, the adhesion to the solar cells 10B1 and 10B2 does not depend on the wettability of a solder material. Instead, the current collecting wire 50 adheres due to the insulating resin body 51, which increases the physical adhesion to the solar cells 10B1 and 10B2. In addition, the current collecting wire 50 is connected at a lower temperature than a solder material and at a lower pressure than a conductive film (CF). As a result, the damages of the solar cells 10B1 and 10B2 caused by the temperature and the pressure decrease. For example, the solar cells 10B1 and 10B2 are prevented from being cracked and the electrodes are less peeled off.

### Second Example

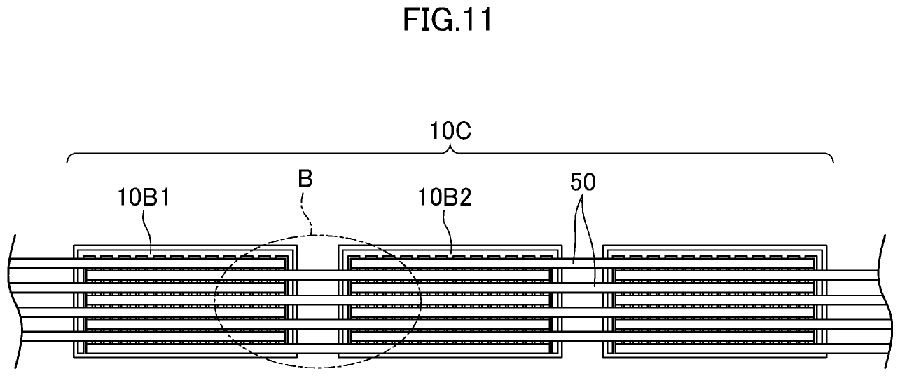

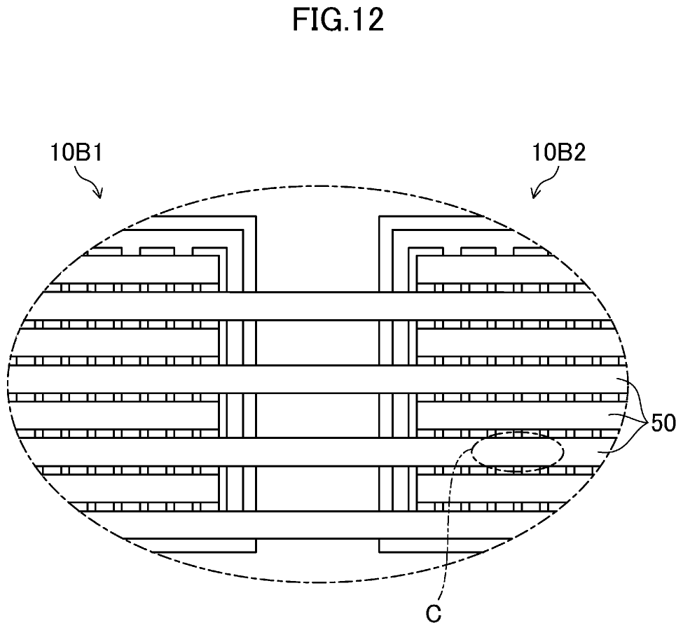

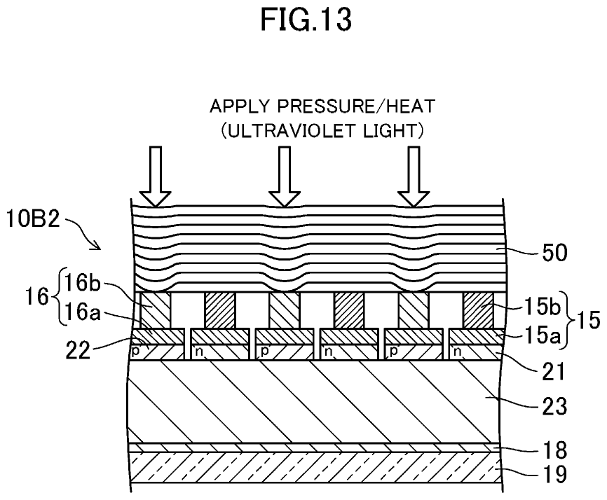

Now, back-electrode type solar cells 10B1 and 10B2 using the current collecting wires 50 according to the embodiment are shown as a second example in FIGS. 11 to 13. In this example as well, FIGS. 11 and 12 are top views of the back surfaces that are opposite to the light receiving surfaces. FIG. 13 is a cross-sectional view with the back surfaces (i.e., the surfaces opposite to the light receiving surfaces) facing upward.

As shown in FIG. 11, the second example employs the current collecting wires 50 to electrically connect the first and second back-electrode type solar cells 10B1 and 10B2 that have the same specifications. FIG. 12 is a partial enlarged view of a region B shown in FIG. 11. FIG. 13 is a partial cross-sectional view of a region C shown in FIG. 12. As shown in FIGS. 12 and 13 (see the description of FIG. 4 as well), in each of the first and second solar cells 10B1 and 10B2, the n-side electrodes 15 (15a, 15b) serving as finger electrodes and the p-side electrodes 16 (16a, 16b) serving as the finger electrodes are alternately arranged on the back surface of the n-type silicon substrate 23. The current collecting wires 50 electrically connect the first and second solar cells 10B1 and 10B2 in series. That is, the current collecting wires 50 are connected to only the n-side electrodes 15 in the first solar cells 10B1, and only the p-side electrodes 16 in the second solar cells 10B2. The n- and p-side electrodes 15 and 16 described herein are metal (e.g., copper (Cu) or silver (Ag)) or transparent (e.g., indium tin oxide (ITO)) electrodes. The metal films 15b and 16b, described herein, constituting the n- and p-side electrodes 15 and 16, respectively, are formed by sputtering, printing, or plating, for example. The metal films 15b and 16b may have a single or multilayer structure. The thickness of the metal films 15b and 16b is not particularly limited but ranges, for example, from 50 nm to 3 μm in one preferred embodiment.

In this manner, the current collecting wires 50 according to the embodiment are used for the electrical connection between the solar cells 10B1 and 10B2. This configuration requires no pad region in which the carriers (i.e., the electrons/holes) generated in the solar cells 10B have shorter lifetimes, and reduces the resistances of the connection between the cells. As a result, the electrical characteristics of the solar cell module improves.

As shown in FIG. 13, in the case of the second solar cell 10B2, the parts of the current collecting wires 50 facing the p-side electrodes (i.e., the finger electrodes) 16 are simultaneously or sequentially pressurized and heated or irradiated with ultraviolet light. That is, any suitable energy is applied to the parts of the current collecting wires 50 facing the p-side electrodes 16. In the parts of the current collecting wires 50 where the energy has been applied, the insulating resin body 51 melts, thereby electrically connecting the encapsulated assembled wires 52 and the p-side electrodes 16 together. Accordingly, the parts of the insulating resin body 51 that physically adhere to the solar cells 10B are dotted.

At this time, in the parts of the current collecting wires 50 where no energy has been applied, the assembled wires 52 remain encapsulated in the insulating resin body 51 and are kept insulated from the n-side electrodes 15, for example. Therefore, if a part of the region of the solar cell 10B adhering to the insulating resin body 51 has a p-type (or a first) conductivity, at least a part of the region of the solar cell 10B not adhering to the insulating resin body 51 has an n-type (or a second) conductivity.

In the case of the second solar cell 10B2 shown in FIG. 13, at least the parts of the p-side electrodes 16 connected to the current collecting wires 50 may be formed to have a greater height than the parts of the n-side electrodes 15. Specifically, the metal films 16b of the p-side electrodes 16 joined to the current collecting wires 50 may be formed to have a greater height than the metal films 15b of the n-side electrodes 15 not joined to the current collecting wires 50. On the other hand, although not shown, in the case of the first solar cell 10B1, at least the metal films 15b of the n-side electrodes 15 connected to the current collecting wires 50 may be formed to have a greater height than the metal films 16b of the p-side electrodes 16.

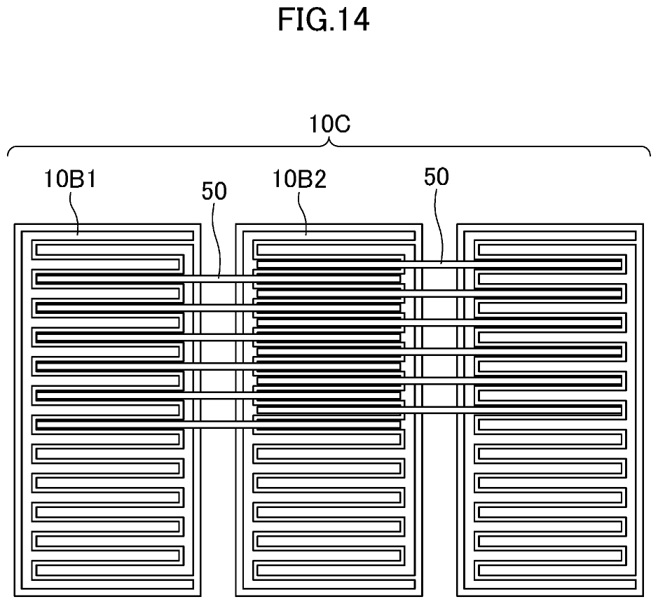

In this second example, as shown in FIG. 11, the short sides of the solar cells 10B1 and 10B2 each having a rectangular planer shape are opposed and connected to each other. As shown in FIG. 14, the long sides may be opposed and connected to each other in a variation.

In the second example, insulation properties of the current collecting wires 50 in a region other than the connection parts are ensured. For this reason, in the case of the back-electrode type solar cell 10B, the connection is made while bypassing the unconnected electrodes having the other polarity on one surface, that is, the back surface. This improves the flexibility in designing of the p-n pattern on the back surface.

In the second example, the insulating resin bodies 51 included in the current collecting wires 50 need to be cured before the process of encapsulating the cell string 10C. This is because, without being cured before the encapsulating, the insulating resin body 51 may melt due to the heating and pressure-bonding and cause defects.

### Third Example

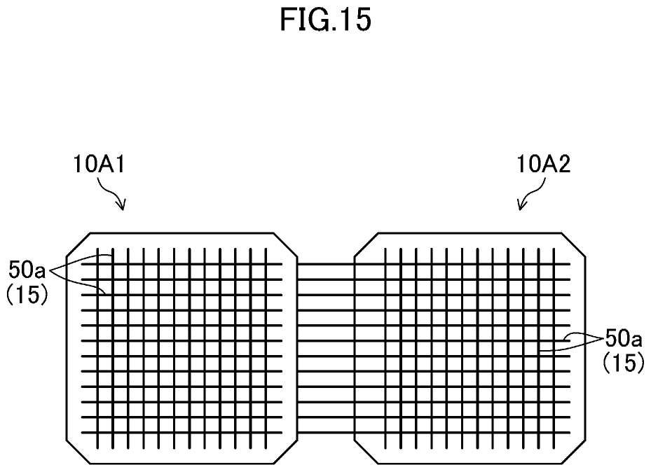

Now, double-sided electrode type solar cells 10A1 and 10A2 using the current collecting wires 50 according to the embodiment are shown as a third example in FIG. 15.

As shown in FIG. 15, the third example employs current collecting wires 50a to electrically connect the first and second double-sided electrode type solar cells 10A1 and 10A2 that have the same specifications. In the third example, as shown in FIG. 3, the double-sided electrode-type solar cells 10A1 and 10A2 each include, as an example, the n-type semiconductor layer 11 on the light receiving surface. The n-side electrodes 15 are thus arranged on the light receiving surface. However, the light receiving surface may be at the p-type semiconductor layer 12 instead of the n-type semiconductor layer 11.

In the third example, the n- and p-side electrodes 15 and 16 (not shown) are integrated by the current collecting wires 50 according to the embodiment into a multi-wire electrode wiring 50a as an example. That is, as shown in FIG. 15, the multi-wire electrode wiring 50a that also serves as the n-side electrodes 15 on the light receiving surface of the second solar cell 10A2 is a multi-wire electrode wiring that also serves as the p-side electrodes 16 (not shown) on the back surface, which is opposite to the light receiving surface, of the first solar cell 10A1 (see also FIG. 1).

In this third example, the multi-wire electrode wiring 50a may be arranged on a conductive film that is formed by printing as an underlying layer. In this case, the conductive film may be a metal (e.g., copper (Cu) or silver (Ag)) or transparent electrode (e.g., indium tin oxide (ITO)). In addition, the multi-wire electrode wiring 50a may be arranged by applying pressure and energy so that the entire surface of the multi-wire electrode wiring 50a connected to the semiconductor substrate 13 (or the conductive film) is electrically connected thereto. Thus, in the third example, the part of the multi-wire electrode wiring 50a that physically adheres to the semiconductor substrate 13 (and eventually the solar cell 10B) is linear.

In this manner, the current collecting wire 50 according to the embodiment is used as the multi-wire electrode wiring 50a serving as the finger electrodes, the tab wire, and the bus bar. This configuration improves the throughput at the time of manufacture and the electrical characteristics of the solar cell module.

The embodiments have been described above as example techniques of the present disclosure, in which the attached drawings and the detailed description are provided. As such, elements illustrated in the attached drawings or the detailed description may include not only essential elements for solving the problem, but also non-essential elements for solving the problem in order to illustrate such techniques. Thus, the mere fact that those non-essential elements are shown in the attached drawings or the detailed description should not be interpreted as requiring that such elements be essential. Since the embodiments described above are intended to illustrate the techniques in the present disclosure, it is intended by the following claims to claim any and all modifications, substitutions, additions, and omissions that fall within the proper scope of the claims appropriately interpreted in accordance with the doctrine of equivalents and other applicable judicial doctrines.

What is claimed is:

1. A wiring member for transporting a carrier generated in a solar cell, the wiring member comprising:
an assembled wire that is an assembly of wires; and
an insulating resin body that encapsulates the assembled wire and exhibits adhesion upon application of energy.

2. The wiring member of claim 1, wherein
the assembled wire is a braided wire obtained by braiding the wires or a stranded wire obtained by twisting the wires together, and
the insulating resin body fills at least a part of a gap between the wires.

3. The wiring member of claim 1, wherein
the insulating resin body is a thermosetting resin cured upon application of heat energy or an ultraviolet curable resin cured upon application of light energy.

4. A solar cell connected to the wiring member of claim 1, wherein
the wiring member is a current collecting wire that collects the carrier, and
in a part of the current collecting wire applied with the energy and pressurized, only the wires form an electrically connected portion to the solar cell.

5. The solar cell of claim 4, wherein
in the part of the current collecting wire applied with the energy and pressurized, only the insulating resin body forms a physically adhering portion to the solar cell.

6. The solar cell of claim 5, wherein
the physically adhering portion is linear or dotted.

7. The solar cell of claim 4, wherein
the solar cell is of a double-sided electrode type including, on a front surface and a back surface thereof, electrodes connected to the current collecting wire, or a back-electrode type including the electrodes only on the back surface.

8. The solar cell of claim 5, wherein
if the solar cell is of the back-electrode type and has the physically adhering portion that is dotted,
a part of a region where the insulating resin body adheres has a first conductivity type, and
at least a part of a region where the insulating resin body does not adhere has a second conductivity type.

9. The solar cell of claim 5, further comprising:
a transparent electrode or a metal electrode, wherein
the physically adhering portion adheres to the transparent electrode or the metal electrode.

10. The solar cell of claim 9, wherein
the transparent electrode or the metal electrode is linear or planar.

11. A solar cell module in which the solar cells of claim 4 are electrically connected by the current collecting wire.
